(19) United States
(12) Patent Application Publication
(10) Pub. No.: US 2024/0057281 A1
(43) Pub. Date: Feb. 15, 2024

(54) SERVER

(71) Applicant: BEIJING TUSEN ZHITU TECHNOLOGY CO., LTD., Beijing (CN)

(72) Inventors: Zhihua MA, Beijing (CN); Haiquan LI, Beijing (CN)

(21) Appl. No.: 18/446,603

(22) Filed: Aug. 9, 2023

(30) Foreign Application Priority Data
Aug. 11, 2022 (CN) 202222116078.2

(51) Int. Cl. H05K 7/20

(52) U.S. Cl. CPC H05K 7/20136; H05K 7/20409

(57) ABSTRACT

Disclosed is a server. The server includes a housing, a processor, a heat dissipating unit, and a fan set. The heat dissipating unit includes a heat dissipating seat module, a first heat dissipating module, and a second heat dissipating module. The heat dissipating seat module contacts the processor. The first heat dissipating module includes a first heat pipe set and a first heat dissipator, and the first heat pipe set connects the heat dissipating seat module and the first heat dissipator. The second heat dissipating module includes a second heat pipe set and a second heat dissipator, and the second heat pipe set connects the heat dissipating seat module and the second heat dissipator. A fan set is disposed at a position on a side wall of the housing. Such a server meets the requirement on heat dissipation of a processor efficiently functioning in an in-vehicle environment.

### CROSS-REFERENCE TO RELATED APPLICATIONS

The present application claims priority to Chinese Patent Application No. 202222116078.2, titled “SERVER”, filed to China National Intellectual Property Administration on Aug. 11, 2022, the content of which is incorporated herein by reference in its entirety.

### TECHNICAL FIELD

The present disclosure relates to a server and, more particularly, to an in-vehicle server.

### BACKGROUND

Generally, an in-vehicle server for decision-making and control is provided on an autonomous vehicle for the need of automatic driving. In-vehicle servers face different challenges than general servers. A large amount of heat is generated during the operation of the server due to the technical complexity involved in the autonomous vehicle, which imposes a high processing efficiency requirement on the in-vehicle server and requires the use of a high-efficiency processor. The conventional structures of in-vehicle servers and those of autonomous vehicles are based on a main board, having boards and peripherals plugged thereto, and to avoid damage to the boards or elements due to vibration in an in-vehicle environment, corresponding support boards are provided inside a server's housing to improve the structural strength. However, these structures limit the heat dissipation space inside the server's housing, and the heat generated by the high-efficiency processor in operation is not easy to be discharged.

It is a technical problem to be solved urgently by those skilled in the art as to how to configure a proper processor heat dissipating structure that is applicable to the structural design of an in-vehicle server.

### SUMMARY

The present disclosure provides a server applicable to an efficient processor required in an in-vehicle environment to provide stable and efficient heat dissipation.

In an aspect of the present disclosure, a server is provided, including:
a housing;
a processor located in the housing;
a heat dissipating unit located in the housing, including:
a heat dissipating seat module contacting the processor;
a first heat dissipating module, the first heat dissipating module including a first heat pipe set and a first heat dissipator, the first heat pipe set connecting the heat dissipating seat module and the first heat dissipator; and
a second heat dissipating module, the second heat dissipating module including a second heat pipe set and a second heat dissipator, the second heat pipe set connecting the heat dissipating seat module and the second heat dissipator; and
a fan set disposed at a position on a side wall of the housing to discharge heat inside the housing out of the housing.

According to the above disclosure, the heat generated in the operation of the processor can be transferred into the housing simultaneously through the heat dissipating seat module contacting the processor, the first heat dissipator, and the second heat dissipator. In addition, the fan set discharges heat inside the housing out of the housing. Thus, the server is applicable to a high-efficiency processor required in an in-vehicle environment, allowing stable and efficient heat dissipation.

### BRIEF DESCRIPTION OF THE DRAWINGS

The accompanying drawings, which are incorporated in and constitute a part of this specification, illustrate embodiments and, together with the description, serve to explain exemplary embodiments of the embodiments. It is apparent that the drawings in the following description are only some rather than all embodiments of the present disclosure, and for a person skilled in the art, other drawings can be obtained according to these drawings without involving any inventive effort. Throughout the drawings, the same reference numerals indicate similar, but not necessarily identical, elements.

FIGS. 1 to 6 are structural diagrams of a server in a process of assembling according to an embodiment of the present disclosure (some elements are not shown);

FIG. 7 is an exploded view of the server according to an embodiment of the present disclosure.

### DETAILED DESCRIPTION

In order that those skilled in the art better understand the technical solution of the present disclosure, the technical solution of the embodiments of the present disclosure will be clearly and completely described below with reference to the accompanying drawings of the embodiments of the present disclosure. It is apparent that the described embodiments are only some rather than all embodiments of the present disclosure. Based on the embodiments of the present disclosure, all the other embodiments obtained by those of ordinary skill in the art without involving any inventive effort shall fall within the scope of the present disclosure.

In the present disclosure, the term “plurality” means two or more, unless otherwise specified. In the present disclosure, unless otherwise noted, the use of the terms “first”, “second”, and the like is intended to distinguish between similar objects and is not intended to limit their positional, temporal, or importance relationships. It is to be understood that the terms so used are interchangeable under appropriate circumstances such that the embodiments of the present disclosure described herein are capable of operation in other ways than those illustrated or otherwise described herein.

The server provided in the embodiments of the present disclosure can be applied to a vehicle with an automatic driving function or a vehicle with an auxiliary driving function, and can also be applied to a vehicle requiring manual driving. The present application does not strictly define the application scenario.

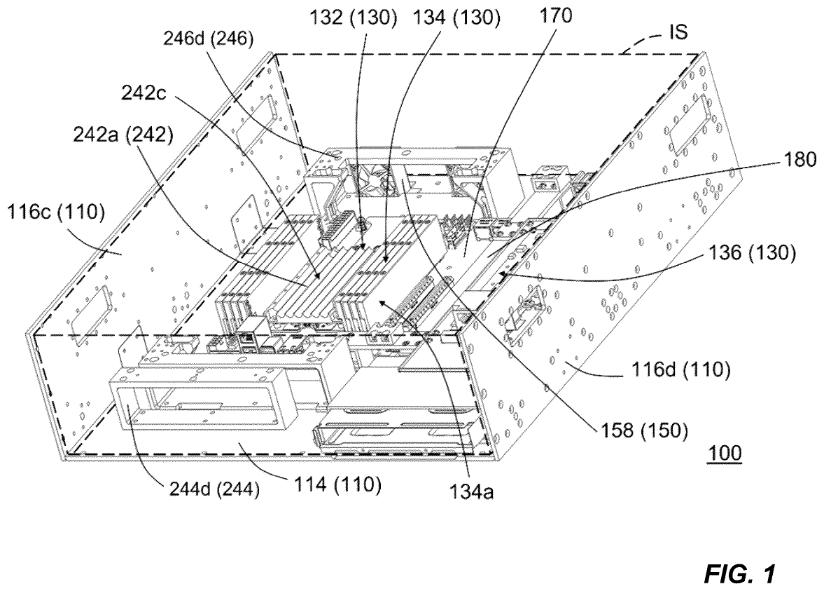

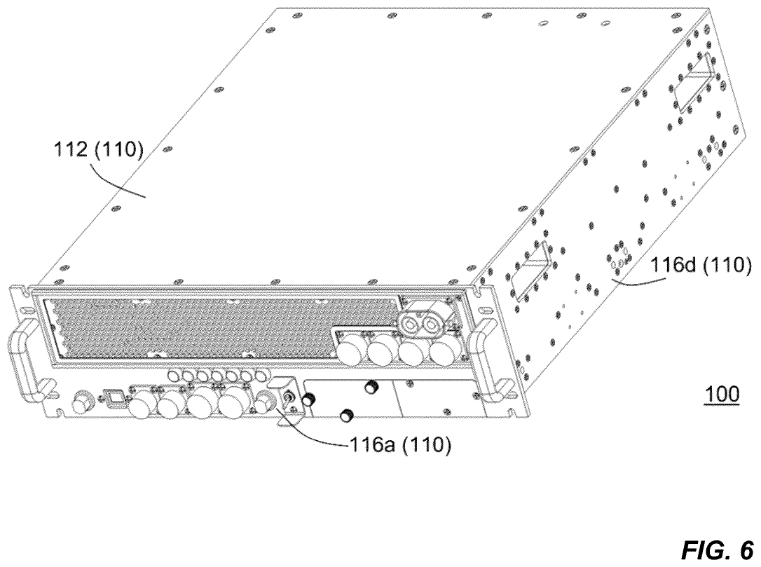

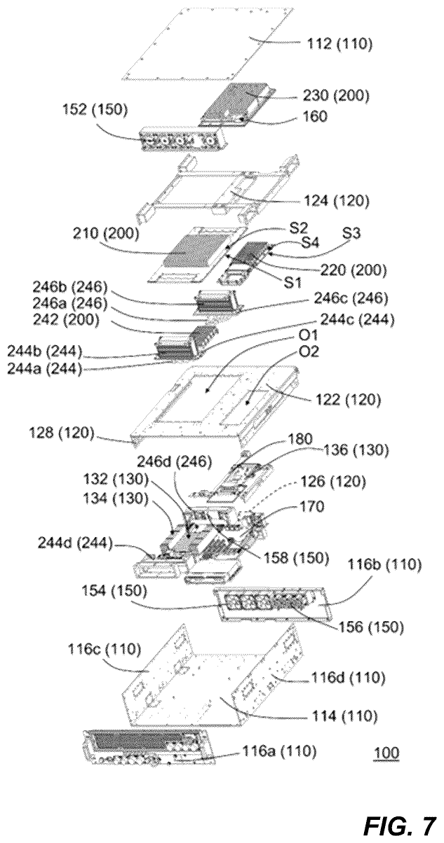

FIGS. 1 to 6 depict a process of mounting the server 100 in an embodiment of the present disclosure. FIG. 7 is an exploded view of the server 100. At least a portion of the illustrations of FIGS. 1 to 6 and FIG. 7 illustrate an interior structure of the server 100 and a relationship among various elements of the server 100.

Referring to FIGS. 1 and 5 to 7, in this embodiment, the server 100 includes a housing 110. The housing 110 includes, for example, an upper board 112, a lower board 114, and a plurality of side walls connecting the upper board 112 and the lower board 114. These side walls include a first side wall 116a, a second side wall 116b, a third side wall 116c, and a fourth side wall 116d. The first side wall 116a is opposite the second side wall 116b, and the third side wall 116c is opposite the fourth side wall 116d. The first side wall 116a is, for example, a front panel of the server 100, and the second side wall 116b is, for example, a back panel of the server 100 opposite the front panel. Further, the third side wall 116c, the lower board 114, and the fourth side wall 116d form a U-shaped board structure. However, these side walls may also be provided with other structures or functions according to actual requirements, and the present disclosure is not limited thereto.

In this embodiment, the housing 110 forms an interior space IS. The interior space IS is, for example, a space surrounded by the upper board 112, the lower board 114, the first side wall 116a, the second side wall 116b, the third side wall 116c, and the fourth side wall 116d. The server 100 further includes a support module 120 in the interior space IS. The support module 120 includes a partition 122 having an opening to divide the interior space IS into an upper space (i.e., a second space IS2 shown in the drawings) and a lower space (i.e., a first space IS1 shown in the drawings). The first space IS1 is located below, i.e., on the side of the lower board 114, and the second space IS2 is located above, i.e., on the side of the upper board 112. Specifically, the lower board 114, the plurality of side walls, and the partition 122 form the lower space, and the upper board 112, the plurality of side walls, and the partition 122 form the upper space.

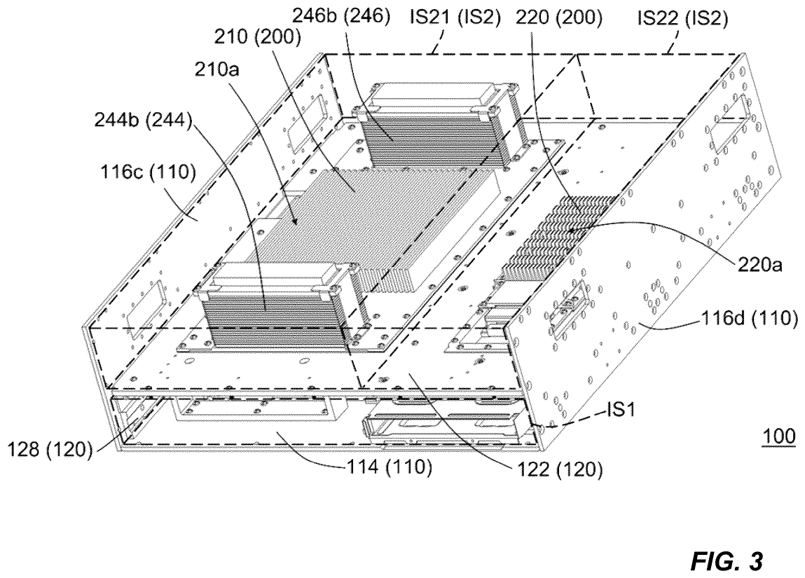

The server 100 further includes a heat-generating element set 130, a heat dissipating unit 200, a main board 170, and a daughterboard 180. The heat-generating element set 130 includes a processor 132 and a memory module 134, both of which are located in the housing 110. The processor 132, the memory module 134, and the main board 170 are all disposed on the lower board 114. Specifically, the processor 132 and the memory module 134 are mounted on the main board 170, and the memory module 134 is disposed adjacent to the processor 132. Specifically, the processor 132 and the memory module 134 are located in the first space IS1. The processor 132 is, for example, a central processing unit (CPU). In some embodiments, nonetheless, the processor 132 may also be a graphics processing unit (GPU). The heat dissipating unit 200 includes a heat sink, i.e., a first heat sink 210. Referring to FIG. 3, the first heat sink 210 has a heat dissipating structure 210a (a first heat dissipating structure) located at one side of the upper space (the second space IS2) to dissipate heat from the heat-generating element set 130, such as the processor 132 and the memory module 134, located in the lower space (the first space IS1).

In this embodiment, the heat sink (the first heat sink 210) and the support module 120 divide the interior space IS into the first space IS1 and the second space IS2. Specifically, the opening of the partition 122 is a first opening O1 for accommodating the first heat sink 210. When the first heat sink 210 is mounted into the first opening O1, the lower board 114, the plurality of side walls, the partition 122, and the first heat sink 210 form the lower space (the first space IS1), and the upper board 112, the plurality of side walls, the partition 122, and the first heat sink 210 form the upper space (the second space IS2). The first space IS1 is, for example, a closed space.

Referring to FIGS. 3 and 7, the first heat sink 210 has a first surface 51 facing the first space IS1 and a second surface S2 facing the second space IS2, and the second surface S2 of the first heat sink 210 has the heat dissipating structure (the heat dissipating structure 210a of FIG. 3). Further, the first surface 51 of the first heat sink 210 contacts the heat-generating element set 130 to dissipate heat from the heat-generating element set 130. Specifically, the first surface 51 of the first heat sink 210 contacts the memory module 134 to dissipate heat from the memory module 134. In some embodiments, the first surface 51 of the first heat sink 210 may also contact the CPU 132 or other elements of the heat-generating element set to dissipate heat therefrom. In this embodiment, the memory module 134 includes at least one memory bank and at least one memory case 134a (shown in FIG. 1). The memory bank is covered by the memory case 134a, and the first surface 51 of the first heat sink 210 contacts the at least one memory case 134a to dissipate heat from the at least one memory case 134a. Specifically, this embodiment depicts eight memory cases 134a that can cover at least one memory bank to provide the heat dissipation and dustproof effect for the memory bank. The heat generated by the memory bank may be directed through the memory case 134a to the first heat sink 210 and into the second space IS2. The heat generated by the heat-generating elements of the heat-generating element set 130 may also be directed to the second space IS2 when the first heat sink 210 contacts or is close to the other heat-generating elements of the heat-generating element set 130.

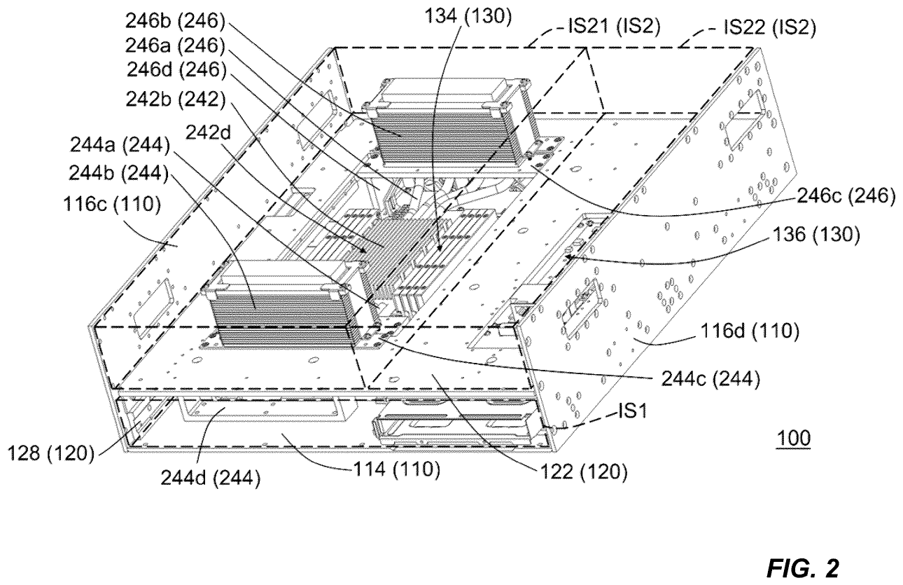

Referring to FIGS. 2 and 7, in this embodiment, the heat dissipating unit 200 is located in the housing 110. The heat dissipating unit 200 further includes a heat dissipating seat module 242, a first heat dissipating module 244, and a second heat dissipating module 246. The heat dissipating seat module 242 is mounted to the processor 132, for example. The heat dissipating seat module 242 includes a base 242a and an upper cover 242b, and one side of the base 242a has a flat surface contacting the processor 132. The first heat dissipating module 244 includes a first heat pipe set 244a and a first heat dissipator 244b, and the first heat pipe set 244a connects the heat dissipating seat module 242 and the first heat dissipator 244b. The second heat dissipating module 246 includes a second heat pipe set 246a and a second heat dissipator 246b, and the second heat pipe set 246a connects the heat dissipating seat module 242 and the second heat dissipator 246b. Specifically, the base 242a of the heat dissipating seat module 242 has a groove structure 242c on the other side of the flat surface to accommodate the first heat pipe set 244a and the second heat pipe set 246a. The upper cover 242b and the base 242a clamp the first heat pipe set 244a and the second heat pipe set 246a such that heat generated by the processor 132 is conducted into the first heat pipe set 244a and the second heat pipe set 246a via the base 242a. In addition, a surface of the upper cover 242b remote from the processor 132 has a heat dissipating structure 242d (a second heat dissipating structure) to dissipate at least a portion of the heat that the processor 132 does not conduct into the first heat pipe set 244a and the second heat pipe set 246a into the first space IS1, so as to allow for the heat dissipation of the processor 132.

With continued reference to FIG. 2, the first heat pipe set 244a includes a plurality of first heat pipes, the second heat pipe set 246a includes a plurality of second heat pipes, and the plurality of first heat pipes and the plurality of second heat pipes are filled with a heat conducting gel or fluid to conduct heat to the first heat dissipator 244b and the second heat dissipator 246b. Nonetheless, in some embodiments, the first heat pipe set 244a and the second heat pipe set 246a may be provided with only one heat pipe or another number of heat pipes depending on the actual needs.

In this embodiment, the heat dissipating seat module 242, the first heat pipe set 244a, and the second heat pipe set 246a are disposed in the first space IS1 (the lower space), and the first heat dissipator 244b and the second heat dissipator 246b are disposed in the second space IS2 (the upper space). The first heat dissipator 244b includes a plurality of first heat dissipating fins in parallel, and the second heat dissipator 246b includes a plurality of second heat dissipating fins in parallel. The first heat dissipating fins and the second heat dissipating fins may discharge heat from the first heat pipe set 244a and the second heat pipe set 246a to the second space IS2. The number of the first heat dissipating fins and the second heat dissipating fins can be appropriately set according to actual requirements, and the present disclosure is not limited thereto.

Referring to FIGS. 2 and 7, in this embodiment, the heat dissipating unit 200 further includes a first heat dissipator bottom board 244c and a second heat dissipator bottom board 246c. The first heat dissipator bottom board 244c carries the first heat dissipator 244b, and the second heat dissipator bottom board 246c carries the second heat dissipator 246b. The opening (the first opening O1) of the partition 122 accommodates the first heat dissipator bottom board 244c and the second heat dissipator bottom board 246c. Further, the first heat pipe set 244a is, for example, extending upward from the first space IS1, through the first heat dissipator bottom board 244c, to enter the second space IS2, and extending through the plurality of first heat dissipating fins of the first heat dissipator 244b. The second heat pipe set 246a is also, for example, extending upward from the first space IS1, through the second heat dissipator floor 246c, to enter the second space IS2, and extending through the plurality of second heat dissipating fins of the second heat dissipator 246b. Specifically, at least one of a projection of the first heat pipe set 244a on the lower board 114 and a projection of the second heat pipe set 246a on the lower board 114 has an overlap region with a projection of the memory module 134 on the lower board 114. In general, it is unable to design the server small enough because the first and second heat pipe sets 244a and 246a have a certain volume and a limited curvature, otherwise the first and second heat pipe sets 244a and 246a interfere with the memory module 134. However, in this embodiment, since the first heat dissipator 244b and the second heat dissipator 246b are disposed in the upper space, the first heat pipe set 244a and the second heat pipe set 246a have a space bent upward. Even if their projections on the lower board 114 have an overlapping region with the projection of the memory module 134 on the lower board 114, the first heat pipe set 244a and the second heat pipe set 246a do not interfere with the memory module 134, which allows the structure of the server 100 in this embodiment to be designed small enough for in-vehicle utility.

In addition, the server 100 further includes a first heat dissipator support 244d and a second heat dissipator support 246d. The first heat dissipator support 244d is disposed between the first heat dissipator bottom board 244c and the lower board 114 to support the first heat dissipator 244b. The second heat dissipator support 246d is disposed between the second heat dissipator bottom board 246c and the lower board 114 to support the second heat dissipator 246b.

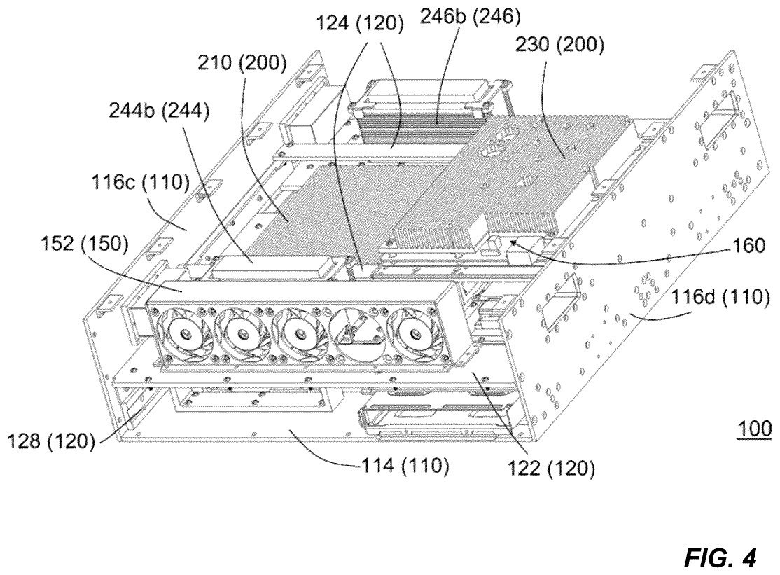

Referring to FIGS. 4, 5, and 7, the support module 120 further includes a first support 124 and a second support 126. The first support 124 is disposed between the partition 122 and the upper board 112, and the second support 126 is disposed between the partition 122 and the lower board 114. The heat-generating element set 130 further includes a network interface card 136 mounted on the daughterboard 180, and the second support 126 supports the daughterboard 180 above the main board 170. Referring to FIGS. 3 and 7, the heat dissipating unit 200 further includes a second heat sink 220, and the partition 122 further includes a second opening O2 for accommodating the second heat sink 220. When the second heat sink 220 is mounted into the second opening O2, the lower board 114, the plurality of side walls, the partition 122, the first heat sink 210, and the second heat sink 220 form the first space IS1. In addition, the support module 120 of the server 100 further includes a partition support 128 disposed between the partition 122 and the lower board 114 to support the partition 122. In some embodiments, the heat-generating element set 130 may also include a plurality of expansion cards mounted to the main board 170 or other boards in the first space IS1.

In this embodiment, the second heat sink 220 has a third surface S3 facing the first space IS1 and a fourth surface S4 facing the second space IS2. The fourth surface S4 of the second heat sink 220 has a heat dissipating structure 220a, and the third surface S3 of the second heat sink 220 contacts the heat-generating element set 130 to dissipate heat from the heat-generating element set 130. Specifically, the third surface S3 of the second heat sink 220 contacts the network interface card 136 to dissipate heat from the network interface card 136. The second heat sink 220 may direct the heat generated by the network interface card 136 to the second space IS2. In this embodiment, the heat dissipating structure 220a is different from the heat dissipating structure 210a, however, the second heat dissipating structure 220a may have the same structure as the heat dissipating structure 210a according to actual requirements.

Referring to FIGS. 4, 5, and 7, in this embodiment, the server 100 further includes a power module 160 to provide a stable DC power supply for the server 100. The first support 124 supports the power module 160 such that the power module 160 is disposed between the first support 124 and the upper board 112. The heat dissipating unit 200 further includes a third heat sink 230 disposed on the power module 160. Specifically, the power module 160 and the third heat sink 230 are stacked above the second heat sink 220 cooling the network interface card 136, and the first heat sink 210 is disposed on the other side of the second space IS2. The upper space of the housing 110, that is, the second space IS2, includes a first portion IS21 and a second portion IS22 (see FIG. 3). A projection of the first portion IS21 on the upper board 112 does not overlap with a projection of the second portion IS22 on the upper board 112. The first heat sink 210 is within the first portion IS21 of the second space IS2, and the second heat sink 220 and the third heat sink 230 are within the second portion IS22 of the second space IS2.

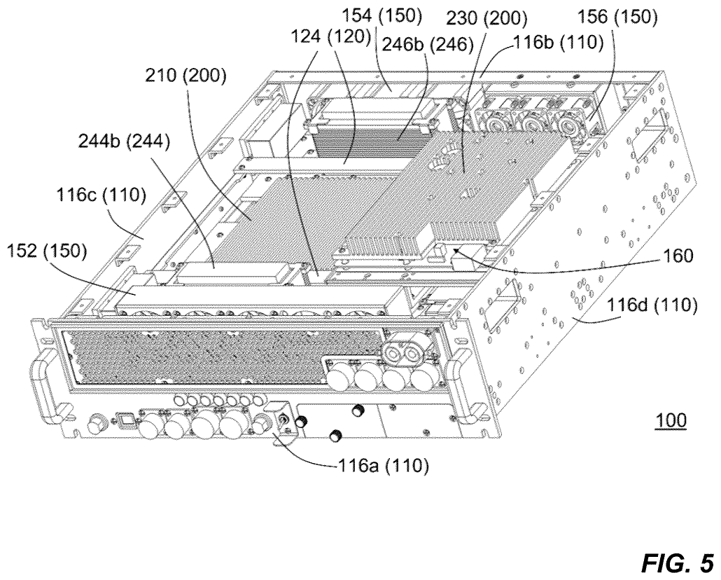

With continued reference to FIGS. 4, 5, and 7, the server 100 further includes a fan set 150 disposed at a position on the housing 110 corresponding to the second space IS2, so as to dissipate heat from the second space IS2. Specifically, the fan set 150 is disposed at a position on a side wall of the housing 110 to discharge heat inside the housing 110 out of the housing 110. The fan set 150 is disposed at a position on at least one of the plurality of side walls. The fan set 150 includes a first fan set 152 and a second fan set 154. The first fan set 152 is disposed at a position on the first side wall 116a of the plurality of side walls, and the second fan set 154 is disposed at a position on the second side wall 116b of the plurality of side walls. The first fan set 152 faces the first heat dissipator 244b, and the second fan set 154 faces the second heat dissipator 246b. The fan set 150 further includes a third fan set 156 disposed at a position on the second side wall 116b of the plurality of side walls. Referring to FIGS. 3 and 4, in this embodiment, the first fan set 152 corresponds to the first portion IS21 and the second portion IS22 of the second space IS2. Further, referring to FIGS. 3 and 5, the second fan set 154 corresponds to the first portion IS21 of the second space IS2, and the third fan set 156 corresponds to the second portion IS22 of the second space IS2.

Specifically, the first fan set 152, the second fan set 154, and the third fan set 156 correspond to positions in the upper space (the second space IS2) to provide an air flow in the second space IS2, thereby discharging heat of the second space IS2 out of the server 100. In this embodiment, the second fan set 154 is positioned adjacent to the first heat sink 210 above the processor 132 and the memory module 134 to dissipate heat from the first heat sink 210. The third fan set 156 is adjacent to the second heat sink 220 above the network interface card 136 and the third heat sink 230 above the power module 160 to dissipate heat from the second heat sink 220 and the third heat sink 230. In this embodiment, since there is a distance between the second side wall 116b and the third heat sink 230, and to improve the heat dissipation efficiency of the third fan set 156, the third fan set 156 may be configured differently from the second fan set 154. The third fan set 156 extends by a greater distance in the second space IS2 than a distance by which the second fan set 154 extends in the second space IS2. As a result, the third fan set 156 is positioned closer to the third heat sink 230 and also closer to the second heat sink 220 to achieve a better heat dissipation effect. However, the distance by which the third fan set 156 extends in the second space IS2 may also be set to be less than or equal to the distance by which the second fan set 154 extends in the second space IS2 according to actual requirements, and the present disclosure is not limited thereto. The number of fans of the first fan set 152, the second fan set 154, and the third fan set 156 may be set according to actual needs, and more fans may be disposed at other positions of the server 100 to achieve a better heat dissipation effect. Further, referring to FIGS. 1 and 7, in this embodiment, the fan set 150 further includes an inner circulation fan set 158 disposed in the lower space (the first space IS1). The inner circulation fan set 158 drives the air to flow in the lower space to further enhance the heat dissipation effect of the server 100 as a whole.

In this embodiment, the heat sink (e.g., the first heat sink 210 and the second heat sink 220) and the support module 120 into the first space IS1 and the second space IS2, and the heat-generating element set 130, such as the processor 132 and the memory module 134, is located in the closed first space IS1. Further, the heat dissipating fins contact the heat-generating element set 130 to dissipate heat from the heat-generating element set 130. Accordingly, heat generated by the heat-generating element set 130 in operation can be conducted into the second space IS2 through the heat sink, and the heat can be discharged out of the server 100 through the fan set 150 cooling the second space IS2. Since the heat-generating element set 130 such as the processor 132 and the memory unit 134 is located in the closed first space IS1 and is blocked by the support module 120 such as the partition 122, dust generated when the fan set 150 dissipates heat from the second space IS2 does not enter the heat-generating element set 130 located in the first space IS1. This enables the server 100 to prevent dust from entering the heat-generating element set 130 while efficiently dissipating heat in the in-vehicle operation environment, thereby achieving a more stable operation of the server 100.

In this embodiment, the partition 122 of the support module 120 provides stability to the overall structure of the server 100. The first support 124 supports the overall structure of the housing 122 of the server 100 and also supports the power module 160. The second support 126 supports the daughterboard 180 above the main board 170. Specifically, the main board 170 is also provided with a plurality of supporting mechanisms to support elements and boards above and reduce the possibility of cantilevering the elements. In this embodiment, the housing 110 and the support module 120 allow for various structural designs so that resonance of the server 100 in the in-vehicle vibration environment can be greatly reduced, whereby the server 100 in the in-vehicle operation environment can be more shock-resistant, and a more stable operation of the server 100 is ensured.

In addition, in this embodiment, heat generated by the processor 132 in operation may be simultaneously transferred into the housing 110 through the heat dissipating seat module 242 contacting the processor 132, the first heat dissipator 244b, and the second heat dissipator 246b. In addition, the fan set 150 discharges heat inside the housing 110 out of the housing 110. Therefore, the server 110 is applicable to a high-efficiency processor required in an in-vehicle environment and allows stable and efficient heat dissipation.

While exemplary embodiments or examples of the present disclosure have been described with reference to the accompanying drawings, it is to be understood that the above exemplary discussion is not intended to be exhaustive or to limit the present disclosure to the precise forms disclosed. Many modifications and variations are possible in light of the above teaching. Accordingly, the disclosed subject matter should not be limited to any single embodiment or example described herein, but rather should be construed in breadth and scope in accordance with the appended claims.

What is claimed is:

1. A server, comprising:
a housing;
a processor located in the housing;
a heat dissipating unit located in the housing, comprising:
a heat dissipating seat module contacting the processor,
a first heat dissipating module, the first heat dissipating module comprising a first heat pipe set and a first heat dissipator, the first heat pipe set connecting the heat dissipating seat module and the first heat dissipator, and
a second heat dissipating module, the second heat dissipating module comprising a second heat pipe set and a second heat dissipator, the second heat pipe set connecting the heat dissipating seat module and the second heat dissipator; and
a fan set disposed at a position on a side wall of the housing to discharge heat inside the housing out of the housing.

2. The server according to claim 1, wherein the housing comprises an upper board, a lower board, and a plurality of side walls connecting the upper board and the lower board, in which the processor is disposed on the lower board, and the fan set is disposed at a position on at least one of the plurality of side walls.

3. The server according to claim 2, further comprising a partition dividing an interior space of the housing into an upper space and a lower space, in which the lower board, the plurality of side walls, and the partition form the lower space, and the upper board, the plurality of side walls, and the partition form the upper space.

4. The server according to claim 3, wherein the heat dissipating unit further comprises a first heat dissipator bottom board and a second heat dissipator bottom board, the first heat dissipator bottom board carrying the first heat dissipator and the second heat dissipator bottom board carrying the second heat dissipator; the partition has an opening to accommodate the first heat dissipator bottom board and the second heat dissipator bottom board, in which the processor is located in the lower space, and the first heat dissipator and the second heat dissipator are located in the upper space.

5. The server according to claim 4, further comprising a memory module and a main board, the processor and the memory module being mounted on the main board, and the memory module being disposed adjacent to the processor, in which at least one of a projection of the first heat pipe set onto the lower board and a projection of the second heat pipe set onto the lower board has an overlap region with a projection of the memory module onto the lower board.

6. The server according to claim 4, further comprising a first heat dissipator support disposed between the first heat dissipator bottom board and the lower board to support the first heat dissipator, and a second heat dissipator support disposed between the second heat dissipator bottom board and the lower board to support the second heat dissipator.

7. The server according to claim 3, further comprising a partition support disposed between the partition and the lower board to support the partition.

8. The server according to claim 3, wherein the heat dissipating unit further comprises a heat sink, and the partition has an opening to accommodate the heat sink; the lower board, the plurality of side walls, the partition, and the heat sink form the lower space, and the upper board, the plurality of side walls, the partition, and the heat sink form the upper space, in which the heat dissipator comprises a first heat dissipating structure located at one side of the upper space.

9. The server according to claim 3, wherein the plurality of side walls comprise a first side wall and a second side wall opposite the first side wall, and the fan set comprises a first fan set and a second fan set, the first fan set being disposed at a position on the first side wall and the second fan set being disposed at a position on the second side wall, in which the first fan set faces the first heat dissipator, and the second fan set faces the second heat dissipator.

10. The server according to claim 9, wherein the first fan set and the second fan set correspond to positions in the upper space.

11. The server according to claim 9, wherein the fan set further comprises an inner circulation fan set disposed in the lower space, the inner circulation fan set driving air to flow in the lower space.

12. The server according to claim 9, wherein the plurality of side walls further comprise a third side wall and a fourth side wall opposite the third side wall, of which the third side wall, the lower board, and the fourth side wall form a U-shaped board structure, the first side wall being a front panel of the server, and the second side wall being a back panel of the server.

13. The server according to claim 1, wherein the heat dissipating seat module comprises a base and an upper cover, one side of the base having a flat surface that contacts the processor, and another side of the base having a groove structure to accommodate the first and second heat pipe sets, in which the upper cover and the base clamp to fix the first and second heat pipe sets.

14. The server according to claim 13, wherein a surface of the upper cover remote from the processor has a second heat dissipating structure.

15. The server according to claim 1, wherein the first heat dissipator comprises a plurality of first heat dissipating fins in parallel, the second heat dissipator comprises a plurality of second heat dissipating fins in parallel, the first heat pipe set comprises a plurality of first heat pipes, the second heat pipe set comprises a plurality of second heat pipes, and the plurality of first heat pipes and the plurality of second heat pipes are filled with a heat conducting gel.

16. The server according to claim 1, wherein the processor is a central processing unit (CPU).
